(19) United States
(12) Patent Application Publication
(10) Pub. No.: US 2005/0122039 A1
(43) Pub. Date: Jun. 9, 2005

(54) Organic luminescence device and its production method

(75) Inventor: Hiroshi Satani, Yawata-shi (JP)

Correspondence Address: MERCHANT & GOULD PC, P.O. BOX 2903, MINNEAPOLIS, MN, 55402-0903, US

(73) Assignee: Matsushita Electric Industrial Co., Ltd., Kadoma-shi (JP)

(21) Appl. No.: 10/506,588

(22) PCT Filed: Mar. 29, 2002
(86) PCT No.: PCT/JP02/03137

(30) Foreign Application Priority Data
Mar. 13, 2002 (JP) 2002-68185

(51) Int. Cl. H05B 33/02

(52) U.S. Cl. 313/506; 156/67; 427/66

(57) ABSTRACT

An organic luminescence device uses a substrate with a gas-barrier film in which a gas-barrier film containing an amorphous oxide and at least two kinds of oxides selected from the group consisting of boron oxide, phosphorus oxide, sodium oxide, potassium oxide, lead oxide, titanium oxide, magnesium oxide, and barium oxide is formed on a substrate. The selected two kinds of oxides are a combination of an oxide of an element having a large atomic radius and an oxide of an element having a small atomic radius. The substrate is made of glass or plastic. As a result, the organic luminescence device using a substrate excellent in gas-barrier capability to prevent the infiltration of oxygen, water vapor, etc. from outside is provided.

### TECHNICAL FIELD

The present invention relates to an organic luminescence device using a substrate with a gas-barrier film, and a method for producing the same.

### BACKGROUND ART

Electroluminescence (EL) panels have characteristics of high visibility, excellent display ability, and capability of high-speed response, and hence, are expected as a future display apparatus for electronic equipment, etc. Therefore, recently, an organic luminescence device used for an EL panel has been studied actively.

In general, the organic luminescence device has a configuration in which an organic luminescence layer containing a fluorescent compound is interposed between a negative electrode and a positive electrode disposed on a glass substrate. When electrons and holes are injected to the organic luminescence layer to be recombined, excitons are generated, and light is emitted when the excitons are deactivated.

However, the organic luminescence device is very susceptible to the infiltration of oxygen, water vapor, etc. from outside, and the luminescence performance thereof is decreased immediately due to the infiltration. Currently, the infiltration of oxygen, water vapor, etc. into the device from outside is prevented by a glass substrate. However, even the glass substrate is insufficient in the organic luminescence device that requires a gas permeation amount of 0.01 g/m²/24 h or less (measuring limit or less).

Furthermore, recently, it also is considered to use a plastic substrate instead of the glass substrate. This is because the plastic substrate is lighter and has higher strength than the glass substrate. However, there is a problem that the plastic substrate has a gas permeability for oxygen, water vapor, etc. larger than that of the glass substrate. At present, it is very difficult to use the plastic substrate for the organic luminescence device.

### DISCLOSURE OF INVENTION

The present invention has been achieved in order to solve the above-mentioned conventional problem, and its object is to provide an organic luminescence device using a substrate excellent in gas-barrier capability, and a method for producing the same.

In order to achieve the above-mentioned object, an organic luminescence device of the present invention uses a substrate with a gas-barrier film in which a gas-barrier film containing an amorphous oxide and at least two kinds of oxides selected from the group consisting of boron oxide, phosphorus oxide, sodium oxide, potassium oxide, lead oxide, titanium oxide, magnesium oxide, and barium oxide is formed on a substrate.

Furthermore, a method for producing an organic luminescence device of the present invention is a method for producing an organic luminescence device using a substrate with a gas-barrier film, including forming a gas barrier film, which contains an amorphous oxide and at least two kinds of oxides selected from the group consisting of boron oxide, phosphorus oxide, sodium oxide, potassium oxide, lead oxide, titanium oxide, magnesium oxide, and barium oxide, on at least one surface of the substrate.

Furthermore, a method for producing an organic luminescence device of the present invention is a method for producing an organic luminescence device using a substrate with a gas-barrier film, including: forming a gas barrier film, which contains an amorphous oxide and at least two kinds of oxides selected from the group consisting of boron oxide, phosphorus oxide, sodium oxide, potassium oxide, lead oxide, titanium oxide, magnesium oxide, and barium oxide on at least one surface of the substrate; and thereafter, subjecting the gas-barrier film to heat treatment.

### BRIEF DESCRIPTION OF DRAWINGS

FIG. 1 is a cross-sectional view of a substrate with a gas-barrier film of the present invention.

FIG. 2 is a cross-sectional view of an organic luminescence device of the present invention.

### BEST MODE FOR CARRYING OUT THE INVENTION

An organic luminescence device of the present invention uses a substrate with a gas-barrier film in which a gas-barrier film containing an amorphous oxide and at least two kinds of oxides selected from the group consisting of boron oxide, phosphorus oxide, sodium oxide, potassium oxide, lead oxide, titanium oxide, magnesium oxide, and barium oxide is formed on a substrate.

As the above-mentioned amorphous oxide, a silicon oxide or the like having a network structure can be used.

Furthermore, other oxides to be contained in the above-mentioned amorphous oxide need to be able to close random holes of the amorphous oxide having a network structure, and it is preferable to combine at least two kinds of an oxide of an element having a large atomic radius and an oxide of an element having a small atomic radius. Examples of the oxide of an element having a large atomic radius include potassium oxide, titanium oxide, barium oxide, lead oxide, and the like. Examples of the oxide of an element having a small atomic radius include boron oxide, sodium oxide, magnesium oxide, phosphorus oxide, and the like.

The substrate used in the present invention can be formed of glass or plastic. As the plastic, acrylic resin, epoxy resin, silicon resin, polyimide resin, polycarbonate resin, polyvinyl alcohol resin, polyethylene resin, etc., or a copolymer thereof can be used. The plastic preferably is radiation-curable resin, and the glass transition temperature of the plastic preferably is 150° C. or higher.

The method for producing an organic luminescence device of the present invention is a method for producing an organic luminescence device using a substrate with a gas-barrier film. According to this method, a gas-barrier film containing an amorphous oxide and at least two kinds of oxides selected from the group consisting of boron oxide, phosphorus oxide, sodium oxide, potassium oxide, lead oxide, titanium oxide, magnesium oxide, and barium oxide is formed at least one surface of a substrate. Thereafter, the gas-barrier film can be subjected to heat treatment, if required. The temperature for the heat treatment preferably is equal to or higher than the film-formation temperature of the gas-barrier film, and equal to or lower than the glass transition temperature of the substrate.

Hereinafter, the embodiments of the present invention will be described with reference to the drawings.

### Embodiment 1

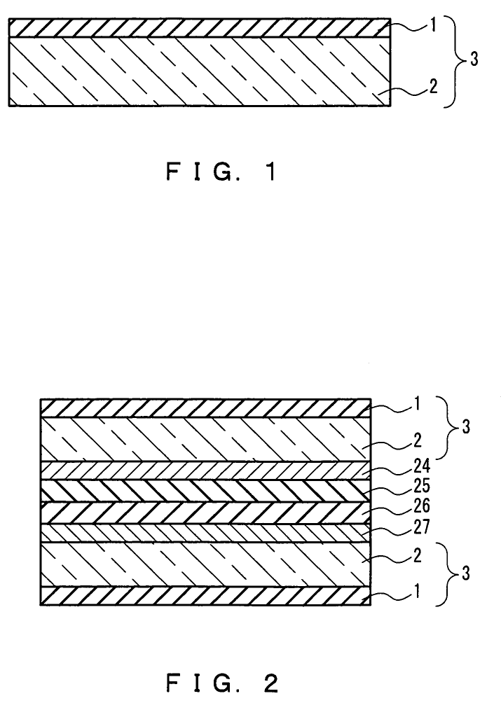

FIG. 1 is a cross-sectional view showing a substrate with a gas-barrier film of the present invention. In FIG. 1, reference numeral 1 denotes a gas-barrier film, 2 denotes a substrate, and 3 denotes a substrate with a gas-barrier film. Furthermore, FIG. 2 is a cross-sectional view showing an organic luminescence device of the present invention. In FIG. 2, reference numeral 24 denotes a negative electrode, 25 an organic luminescence layer, 26 denotes a hole transporting layer, and 27 denotes a positive electrode.

First, a gas-barrier film 1 (thickness: 150 Å) composed of silicon oxide that is an amorphous oxide, boron oxide, and titanium oxide was formed on one surface of the substrate 2 made of glass, using RF magnetron sputtering, whereby a substrate 3 with a gas-barrier film was produced. The RF magnetron sputtering was performed under the condition that a pellet of boron oxide and titanium oxide was placed on a target made of silicon oxide with the glass substrate 2 kept at a constant temperature.

Herein, the oxygen gas permeation amount of the substrate 3 with a gas-barrier film was measured to be 0.01 g/m²/24 h or less (measuring limit or less).

Two substrates 3 with a gas-barrier film formed as described above were prepared, and the negative electrode 24, the organic luminescence layer 25, the hole transporting layer 26, and the positive electrode 27 were placed by an ordinary method between the substrates 3 with a gas-barrier film, each being placed with the gas-barrier film 1 outside, whereby an organic luminescence device was produced.

In the gas-barrier film of the present embodiment, the boron oxide and the titanium oxide close gaps of the silicon oxide composed of a network structure, so that the permeation of gas is suppressed. Consequently, in the organic luminescence device using the substrate with a gas-barrier film of the present embodiment, oxygen, water vapor, etc. did not enter the device from outside, so that luminescence failures did not occur.

### Embodiment 2

An organic luminescence device was produced in the same way as in Embodiment 1, except that a phosphorus oxide and a lead oxide were used in place of the boron oxide and the titanium oxide. The oxygen gas permeation amount of the substrate with a gas-barrier film was measured to be 0.01 g/m²/24 h or less (measuring limit or less).

In the gas-barrier film of the present embodiment, the phosphorus oxide and the lead oxide close gaps of the silicon oxide composed of a network structure, so that the permeation of gas is suppressed. Consequently, in the organic luminescence device using the substrate with a gas-barrier film of the present embodiment, oxygen, water vapor, etc. did not enter the device from outside, so that luminescence failures did not occur.

### Embodiment 3

An organic luminescence device was produced in the same way as in Embodiment 1, except that a sodium oxide and a barium oxide were used in place of the boron oxide and the titanium oxide. The oxygen gas permeation amount of the substrate with a gas-barrier film was measured to be 0.01 g/m²/24 h or less (measuring limit or less).

In the gas-barrier film of the present embodiment, the sodium oxide and the barium oxide close gaps of the silicon oxide composed of a network structure, so that the permeation of gas is suppressed. Consequently, in the organic luminescence device using the substrate with a gas-barrier film of the present embodiment, oxygen, water vapor, etc. did not enter the device from outside, so that luminescence failures did not occur.

### Embodiment 4

An organic luminescence device was produced in the same way as in Embodiment 1, except that a magnesium oxide and a potassium oxide were used in place of the boron oxide and the titanium oxide. The oxygen gas permeation amount of the substrate with a gas-barrier film was measured to be 0.01 g/m²/24 h or less (measuring limit or less).

In the gas-barrier film of the present embodiment, the magnesium oxide and the potassium oxide close gaps of the silicon oxide composed of a network structure, so that the permeation of gas is suppressed. Consequently, in the organic luminescence device using the substrate with a gas-barrier film of the present embodiment, oxygen, water vapor, etc. did not enter the device from outside, so that luminescence failures did not occur.

### Embodiment 5

An organic luminescence device was produced in the same way as in Embodiment 1, except that a lead oxide further was added to the boron oxide and the titanium oxide. The oxygen gas permeation amount of the substrate with a gas-barrier film was measured to be 0.01 g/m²/24 h or less (measuring limit or less).

In the gas-barrier film of the present embodiment, the boron oxide, the titanium oxide, and the lead oxide close gaps of the silicon oxide composed of a network structure, so that the permeation of gas is suppressed. Consequently, in the organic luminescence device using the substrate with a gas-barrier film of the present embodiment, oxygen, water vapor, etc. did not enter the device from outside, so that luminescence failures did not occur.

In the present embodiment, since three kinds of other oxides are contained in the silicon oxide, the gaps of the silicon oxide composed of a network structure can be closed more completely, whereby the permeation of gas further is suppressed.

As described above, in the above-mentioned Embodiments 1 to 5, although the gas-barrier film was provided on only one surface of a glass substrate. However, it is more effective to provide the gas-barrier film on both surfaces of the glass substrate. Furthermore, although glass was used as a material for the substrate with a gas-barrier film, plastic also can be used. In this case, plastic has a higher gas permeability compared with glass, so that it is preferable to provide a gas-barrier film on both surfaces of a plastic substrate. Furthermore, by forming a gas-barrier film on both surfaces of a plastic substrate, the strain of a substrate due to the difference in coefficient of thermal expansion can be reduced.

### Industrial Applicability

As described above, according to the present invention, by using a substrate with a gas-barrier film in which a gas-barrier film containing an amorphous oxide and at least two kinds of oxides selected from the group consisting of boron oxide, phosphorus oxide, sodium oxide, potassium oxide, lead oxide, titanium oxide, magnesium oxide, and barium oxide is formed on a substrate is formed on a substrate, the gaps of the amorphous oxide composed of a network structure can be closed with the oxides, so that the permeation of gas can be suppressed. Consequently, when the substrate with a gas-barrier film is used for the organic luminescence device, the following advantageous effects can be obtained: oxygen, water vapor, etc. can be prevented from entering the device from outside, and luminescence failures do not occur.

1. An organic luminescence device using a substrate with a gas-barrier film in which the gas-barrier film containing an amorphous oxide and at least two kinds of oxides selected from the group consisting of boron oxide, phosphorus oxide, sodium oxide, potassium oxide, lead oxide, titanium oxide, magnesium oxide, and barium oxide is formed on the substrate.

2. The organic luminescence device according to claim 1, wherein the selected at least two kinds of oxides are a combination of an oxide of an element having a large atomic radius and an oxide of an element having a small atomic radius.

3. The organic luminescence device according to claim 1, wherein the substrate is made of glass or plastic.

4. The organic luminescence device according to claim 3, wherein the plastic is at least one resin selected from the group consisting of acrylic resin, epoxy resin, silicon resin, polyimide resin, polycarbonate resin, polyvinyl alcohol resin, and polyethylene resin, or a copolymer thereof.

5. A method for producing an organic luminescence device using a substrate with a gas-barrier film, comprising forming the gas barrier film, which contains an amorphous oxide and at least two kinds of oxides selected from the group consisting of boron oxide, phosphorus oxide, sodium oxide, potassium oxide, lead oxide, titanium oxide, magnesium oxide, and barium oxide, on at least one surface of the substrate.

6. The method for producing an organic luminescence device according to claim 5, wherein the selected at least two kinds of oxides are a combination of an oxide of an element having a large atomic radius and an oxide of an element having a small atomic radius.

7. The method for producing an organic luminescence device according to claim 5, wherein the substrate is made of glass or plastic.

8. The method for producing an organic luminescence device according to claim 7, wherein the plastic is at least one resin selected from the group consisting of acrylic resin, epoxy resin, silicon resin, polyimide resin, polycarbonate resin, polyvinyl alcohol resin, and polyethylene resin, or a copolymer thereof.

9. A method for producing an organic luminescence device using a substrate with a gas-barrier film, comprising: forming the gas barrier film, which contains an amorphous oxide and at least two kinds of oxides selected from the group consisting of boron oxide, phosphorus oxide, sodium oxide, potassium oxide, lead oxide, titanium oxide, magnesium oxide, and barium oxide on at least one surface of the substrate; and thereafter, subjecting the gas-barrier film to heat treatment.

10. The method for producing an organic luminescence device according to claim 9, wherein a temperature of the heat treatment is equal to or higher than a film-formation temperature of the gas-barrier film, and equal to or lower than a glass transition temperature of the substrate.

11. The method for producing an organic luminescence device according to claim 9, wherein the selected at least two kinds of oxides are a combination of an oxide of an element having a large atomic radius and an oxide of an element having a small atomic radius.

12. The method for producing an organic luminescence device according to claim 9, wherein the substrate is made of glass or plastic.

13. The method for producing an organic luminescence device according to claim 12, wherein the plastic is at least one resin selected from the group consisting of acrylic resin, epoxy resin, silicon resin, polyimide resin, polycarbonate resin, polyvinyl alcohol resin, and polyethylene resin, or a copolymer thereof.
